(19) United States
(12) Patent Application Publication
(10) Pub. No.: US 2006/0219281 A1
(43) Pub. Date: Oct. 5, 2006

(54) Thermoelectric transducer

(75) Inventors: Isao Kuroyanagi, Anjo-city (JP); Akio Matsuoka, Takahama-city (JP); Yasuhiko Niimi, Handa-city (JP); Takashi Yamamoto, Okazaki-city (JP); Yukinori Hatano, Okazaki-city (JP); Shizuo Maruo, Okazaki-city (JP); Fumiaki Nakamura, Kariya-city (JP)

Correspondence Address: HARNESS, DICKEY & PIERCE, P.L.C., P.O. BOX 828, BLOOMFIELD HILLS, MI, 48303, US

(73) Assignee: DENSO Corporation, Kariya-city (JP)

(21) Appl. No.: 11/397,546

(22) Filed: Apr. 4, 2006

(30) Foreign Application Priority Data
Apr. 5, 2005 (JP) 2005-109053

(51) Int. Cl. H01L 35/34; H01L 35/28

(52) U.S. Cl. 136/201; 136/204

(57) ABSTRACT

In a thermoelectric transducer, a plurality of P-type thermoelectric devices and N-type thermoelectric devices are alternately arranged on an insulating board, and each of a plurality of electrode members is connected to two end portions of adjacent N-type and P-type thermoelectric devices for electrically connecting the adjacent N-type and P-type thermoelectric devices. Furthermore, a plurality of heat exchanging members each of which includes an electrode portion connectable to the electrode member and a heat exchanging portion for exchanging heat transmitted from the electrode portion are located at two sides of a thermoelectric device substrate to form a heat absorbing part and a heat radiating part partitioned from each other. The electrode portions and the heat exchanging portions have, respectively, the same shapes, and the electrode portions and the heat exchanging portions are arranged in the same direction in all the heat exchanging members of each heat absorbing or radiating part.

### CROSS REFERENCE TO RELATED APPLICATION

This application is based on Japanese Patent Application No. 2005-109053 filed on Apr. 5, 2005, the contents of which are incorporated herein by reference in its entirety.

### BACKGROUND OF THE INVENTION

1. Field of the Invention

The present invention relates to a thermoelectric transducer that has a series circuit including N-type thermoelectric devices and P-type thermoelectric devices and absorbs or radiates heat when a DC current is passed through the series circuit. More particularly, present invention relates to the shape of heat exchanging members located at connection portions between adjacent thermoelectric devices.

2. Description of the Related Art

As one of conventional thermoelectric transducers, there is proposed a thermoelectric transducer that has N-type thermoelectric devices and P-type thermoelectric devices alternately arranged in the shape of a plane. In this thermoelectric transducer, the respective thermoelectric devices have one-side electrode members mounted on their one-side surfaces and have other-side electrode members mounted on their other-side surfaces, thereby all thermoelectric devices are connected to each other in series (refer to JP-A-2003-124531 corresponding to U.S. Pat. No. 6,815,814).

In the thermoelectric devices of this type, heat exchanging members for absorbing or radiating heat transmitted from the one-side electrode members and the other-side electrode members are integral with the one-side electrode members and the other-side electrode members. Furthermore, adjacent thermoelectric devices are arranged to be electrically insulated from each other. Accordingly, it is difficult to accurately arrange the thermoelectric devices each having a small size and the electrode members, thereby assembling steps for manufacturing the thermoelectric transducer are increased.

Furthermore, when the heat exchanging members are simply arranged at connection portions between adjacent thermoelectric devices in accordance with the arrangement of the thermoelectric devices, it is difficult to effectively improve thermoelectric converting efficiency in the thermoelectric transducer.

### SUMMARY OF THE INVENTION

In view of the foregoing problems, it is an object of the present invention to provide a thermoelectric transducer, which can be easily manufactured while improving thermoelectric converting efficiency.

According to an aspect of the present invention, in a thermoelectric transducer, a thermoelectric device substrate includes a plurality of P-type thermoelectric devices, a plurality of N-type thermoelectric devices, and an insulating board for holding the plurality of P-type thermoelectric devices and N-type thermoelectric devices, and the plurality of P-type thermoelectric devices and N-type thermoelectric devices are alternately arranged on the insulating board. Each of a plurality of electrode members is connected to two end portions of adjacent N-type thermoelectric device and P-type thermoelectric device for electrically connecting the adjacent N-type thermoelectric device and P-type thermoelectric device. In addition, the thermoelectric transducer includes a plurality of heat exchanging members each of which includes an electrode portion connectable to the electrode member, and a heat exchanging portion for exchanging heat transmitted from the electrode portion. In the thermoelectric transducer, the plurality of heat exchanging members are located at two sides of the thermoelectric device substrate to form a heat absorbing part and a heat radiating part partitioned from each other by the thermoelectric device substrate. In addition, the electrode portions and the heat exchanging portions have, respectively, the same shapes, in all the heat exchanging members, and the electrode portions and the heat exchanging portions are arranged in the same direction in all the heat exchanging members of each of the heat absorbing part and the heat radiating part. Accordingly, it is possible to use one type of the heat exchanging members, thereby effectively reducing manufacturing cost of the heat exchanging members.

For example, the plurality of N-type thermoelectric devices and the plurality of P-type thermoelectric devices are arranged to form plural thermoelectric device groups arranged in plural lines in an arrangement direction, and each of the plural thermoelectric device groups is constructed with a pair of the N-type thermoelectric device and the P-type thermoelectric device electrically connected to each other by the electrode member. In this case, two heat exchanging members are arranged on one electrode member that connects the N-type thermoelectric device and the P-type thermoelectric device in a direction perpendicular to the arrangement direction at an outer end of the thermoelectric device groups, and the N-type thermoelectric device and the P-type thermoelectric device in each thermoelectric device group inside of the outer end are electrically connected by one electrode member extending in a direction parallel to the arrangement direction. Furthermore, the two heat exchanging members extend in the arrangement direction at the outer end of the thermoelectric device groups. Therefore, thermoelectric converting efficiency can be effectively improved.

Each of the heat exchanging members can be formed into approximately a U-shape having a bottom part used as the electrode portion and protruding portions used as the heat exchanging portion protruding from the bottom portion at two ends of the bottom portion, and each of the electrode members can be elongated in an extension direction to electrically connect the N-type thermoelectric device and the P-type thermoelectric device of each thermoelectric device group. In this case, a part of each electrode portion of the two heat exchanging members can be bonded to the electrode member at the outer end of the thermoelectric device groups. Furthermore, each of the electrode portions and each of the heat exchanging portions of the two heat exchanging members at the outer end of the thermoelectric device groups can extend in a direction approximately perpendicular to the extending direction of the electrode member at the outer end of the thermoelectric device groups. Here, a surface area of each electrode member can be set approximately equal to a surface area of the electrode portion of each heat exchanging member.

In addition, at least in the heat radiating part, the two heat exchanging members can be arranged on the one electrode member to extend in the arrangement direction at the outer end of the thermoelectric device groups.

Alternatively, two heat exchanging members can be arranged on one electrode member at an outer end of the thermoelectric device groups, and a surface area of the electrode member arranged at the outer end of the thermoelectric device groups can be set to connect the N-type thermoelectric device and the P-type thermoelectric device in a direction perpendicular to the arrangement direction and to connect the electrode portions of the two heat exchanging members with each other.

According to another aspect of the present invention, a thermoelectric transducer includes: a thermoelectric device substrate that has a plurality of P-type thermoelectric devices, a plurality of N-type thermoelectric devices, and an insulating board for holding the plurality of P-type thermoelectric devices and N-type thermoelectric devices alternately arranged on the insulating board; and a plurality of heat exchanging members each of which includes an electrode portion bonded to two end portions of adjacent N-type thermoelectric device and P-type thermoelectric device for electrically connecting the adjacent N-type thermoelectric device and P-type thermoelectric device, and a heat exchanging portion for exchanging heat transmitted from the electrode portion. In this thermoelectric transducer, the plurality of heat exchanging members are located at two sides of the thermoelectric device substrate to form a heat absorbing part and a heat radiating part partitioned from each other by the thermoelectric device substrate, the electrode portions and the heat exchanging portions have, respectively, the same shapes in all the heat exchanging members, and the electrode portions and the heat exchanging portions are arranged in the same direction in all the heat exchanging members in each of the heat absorbing part and the heat radiating part. Accordingly, all the heat exchanging member can be formed into one type, and the thermoelectric transducer can be easily formed.

Even in this case, two heat exchanging members can be arranged on one thermoelectric device group at an outer end of the thermoelectric device groups, such that the electrode portions of the two heat exchanging members are located, respectively, to the N-type thermoelectric device and the P-type thermoelectric device, and the N-type thermoelectric device and the P-type thermoelectric device of the one thermoelectric device group can be electrically connected to each other. Furthermore, a part of each electrode portion of the two heat exchanging members can be bonded to the electrode portion at the outer end of the thermoelectric device groups.

### BRIEF DESCRIPTION OF THE DRAWINGS

The above and other objects, features and advantages of the present invention will become more apparent from the following detailed description of preferred embodiments made with reference to the accompanying drawings, in which:

FIG. 1A is a top view showing a part of a thermoelectric transducer in a first embodiment of the present invention, and FIG. 1B is a bottom view showing a part of the thermoelectric transducer in the first embodiment;

FIG. 2A is a schematic disassembled perspective view showing the part of IIA in FIG. 1A, and FIG. 2B is a schematic disassembled perspective view showing the part of IIB in FIG. 1A;

FIG. 3 is a sectional view taken on the line III-III shown in FIG. 1A;

FIG. 4 is a schematic sectional view taken on the line IV-IV shown in FIG. 3;

FIG. 5 is a schematic sectional view taken on the line V-V shown in FIG. 3;

FIG. 6 is a disassembled schematic view showing a structure of the thermoelectric transducer in the first embodiment of the present invention;

FIG. 7A is a schematic front view showing a shape of a heat exchanging member in the first embodiment, FIG. 7B is a side view showing the heat exchanging member, and FIG. 7C is a cross-sectional view taken along the line VIIC-VIIC of FIG. 7A;

FIG. 8A is a schematic view showing a part of a thermoelectric transducer according to a second embodiment of the present invention, and FIG. 8B is a schematic disassembled perspective view corresponding to FIG. 2A, according to the second embodiment;

FIG. 9 is a schematic view showing a thermoelectric transducer according to a third embodiment of the present invention;

FIG. 10 is a cross-sectional view taken along the line X-X of FIG. 9; and

FIG. 11A and FIG. 11B are a front view and a side view, respectively, showing a heat exchanging member according to a modification of the present invention, and FIG. 11C is a cross sectional view taken along the line XIC-XIC of FIG. 11A.

### DETAILED DESCRIPTION OF THE PREFERRED EMBODIMENTS

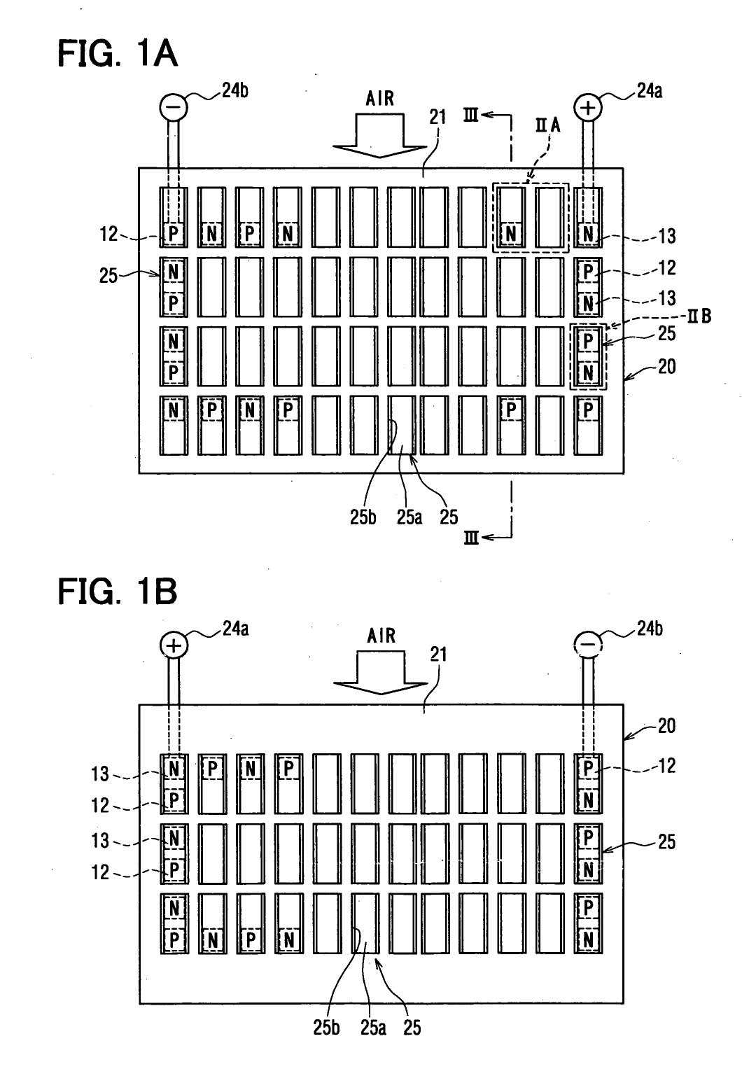

A first embodiment of the present invention will be described with reference to FIGS. 1-7C.

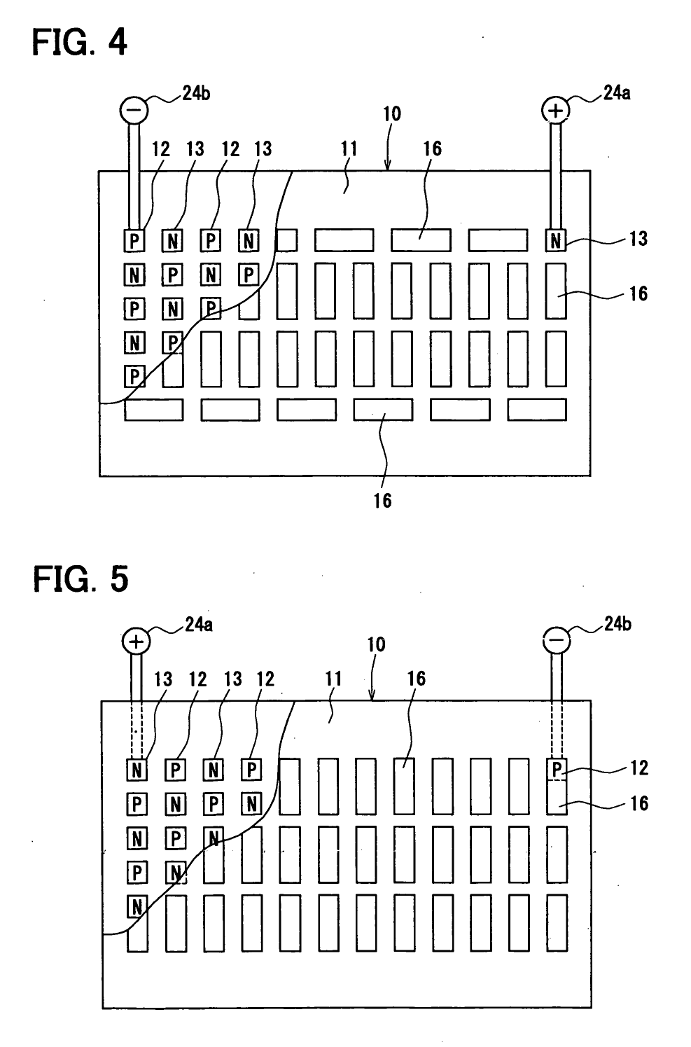

FIGS. 1A and 1B are top view and bottom view showing a thermoelectric transducer according to the first embodiment. The thermoelectric transducer of this embodiment, as shown in FIG. 3 and FIG. 4, is constructed with: a thermoelectric device substrate 10 with a plurality of P-type thermoelectric devices 12 and a plurality of N-type thermoelectric devices 13 set in an array; electrode members 16 each of which electrically connects the P-type thermoelectric device 12 with N-type thermoelectric devices 13, which are adjacent to each other, in series; a pair of heat absorbing/radiating substrates 20 each of which has a plurality of heat exchanging members 25 bonded to the electrode members 16 in such a way as to transmit heat; and a pair of case members 28.

The thermoelectric device substrate 10, as shown in FIG. 4 and FIG. 5, is a thermoelectric device assembly that is integrally constructed of: a first insulating board 11 (holding plate) made of a plate-shaped insulating material (for example, glass epoxy, PPS resin, LCP resin, or PET resin); and plural groups of thermoelectric devices formed of the plurality of P-type thermoelectric devices 12 and the plurality of N-type thermoelectric devices 13 alternately arranged on the first insulating board 11 in plural lines.

The P-type thermoelectric device 12 is an extremely small component constructed of a P-type semiconductor made of a Bi—Te based compound, and the N-type thermoelectric device 13 is an extremely small component constructed of an N-type semiconductor made of the Bi—Te based compound. The thermoelectric device substrate 10 is integrally formed in such a way that the P-type thermoelectric devices 12 and the N-type thermoelectric devices 13 are arranged on the first insulating board 11 in a lattice pattern. At this time, the P-type thermoelectric devices 12 and the N-type thermoelectric devices 13 are formed in such a way as to protrude their top end surfaces and bottom surfaces from the first insulating board 11.

The electrode member 16 is an electrode that is formed of plate-shaped conductive metal such as copper and electrically directly connects the P-type thermoelectric device 12 with the N-type thermoelectric device 13, which are adjacent to each other, among the thermoelectric device groups 12, 13 arranged on the thermoelectric device substrate 10. All of the electrode members 16, as shown in FIG. 4 and FIG. 5, are formed in a unified same rectangular shape to cover the end surfaces of the adjacent thermoelectric devices 12, 13.

The electrode members 16 are arranged at specified positions corresponding to the state of arrangement of the thermoelectric devices 12, 13 arranged on the thermoelectric device substrate 10, and are bonded to the thermoelectric devices 12, 13. In other words, the electrode members 16 are arranged on both end surfaces of the adjacent thermoelectric devices 12, 13 so that adjacent thermoelectric devices 12, 13 are electrically connected in series by each electrode member 16.

The thermoelectric devices 12, 13 arranged on a left upper end and a right upper end in the drawing have terminals 24a and 24b, respectively. A positive terminal and a negative terminal of a DC power source (not shown) are connected to these terminals 24a and 24b, respectively.

As shown in FIGS. 4 and 5, the electrode members 16 are arranged such that the adjacent thermoelectric devices 12, 13 are connected to each other in such a way as to form an electrical PN junction on one surface side (refer to FIG. 4) of the thermoelectric device substrate 10 and to form an electrical NP junction on the other surface side (refer to FIG. 5). The electrode members 16 are soldered to the end surfaces of the thermoelectric devices 12, 13, respectively, for example.

The electrode members 16 arranged on one surface side (refer to FIG. 4) of the thermoelectric device substrate 10 are different in the direction of arrangement between a case where the electrode members 16 are arranged on the thermoelectric devices 12, 13 at the outside end of thermoelectric device groups and a case where the electrode members 16 are arranged on the thermoelectric devices 12, 13 at the inside of the outside end of the thermoelectric device groups.

As shown in FIG. 4, when the electrode members 16 are arranged on the thermoelectric devices 12, 13 at the outside end of the thermoelectric device groups, the electrode members 16 are arranged in a direction perpendicular to the arrangement of the thermoelectric device groups, whereas when the electrode members 16 are arranged on the thermoelectric devices 12, 13 at the inside of the outside end of the thermoelectric device groups, the electrode members 16 are arranged in a direction along the arrangement of the thermoelectric device groups.

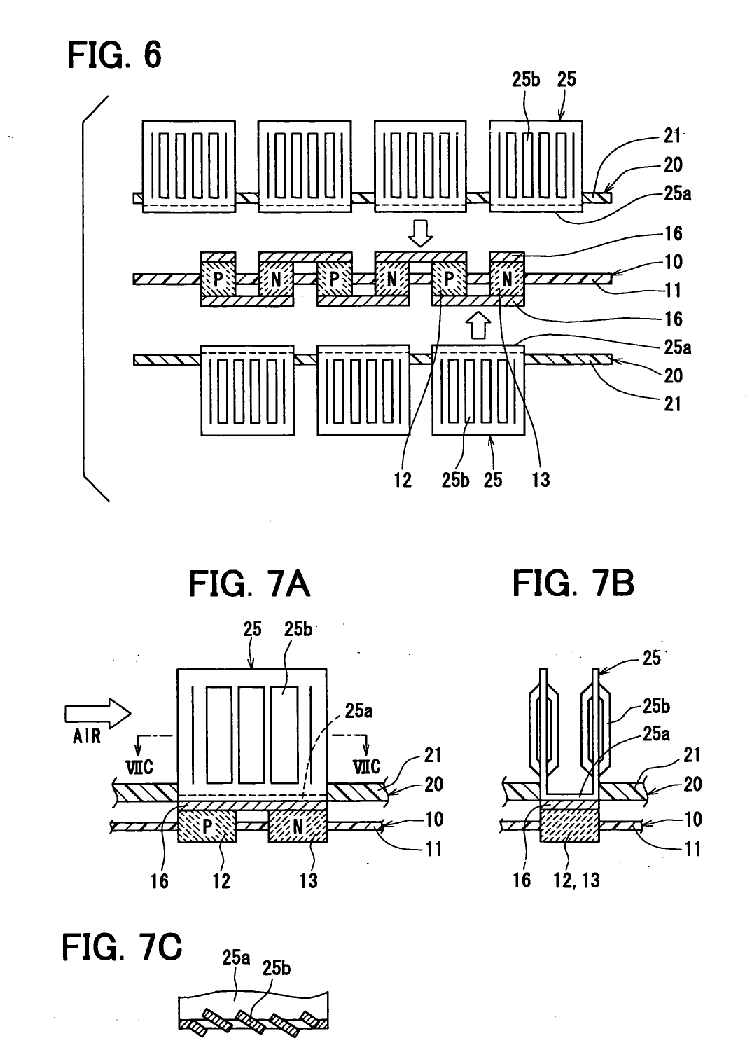

The heat absorbing/radiating substrate 20 of the heat exchanging member assembly, as shown in FIG. 3 and FIG. 6, is integrally constructed of a second insulating board 21 (i.e., holding plate) made of a plate-shaped insulating material (for example, glass epoxy, PPS resin, LCP resin, or PET resin) and a plurality of heat exchanging members 25.

Each of the heat exchanging members 25 is formed of a thin plate of conductive material such as copper, and is formed nearly in the shape of a letter U in cross section as shown in FIGS. 7A-7C. Each of the heat exchanging members 25 has an electrode portion 25a formed in the shape of a plane at the bottom, and a heat exchanging portion (louver) 25b which is formed in the shape of a louver at a portion extended outward from two ends of the electrode portion 25a. The heat exchanging portion 25b is disposed for absorbing and radiating heat transmitted from the electrode portion 25a and is formed integrally with the electrode portion 25a by cutting and raising the thin plate.

In the embodiment, a plurality of heat exchanging members 25 are integrated with the second insulating board 21 such that the electrode portions 25a are arranged at predetermined positions corresponding to the arrangement of the electrode members 16. One end surface of each electrode portion 25a has a shape and a surface area approximately equal to the surface shape and the surface area of the electrode member 16 so as to be bonded to the electrode member 16.

Furthermore, the heat exchanging member 25 is formed integrally with the second insulating board 21 such that the one end surface of each electrode portion 25a slightly protrudes from one surface of the second insulating board 21 toward the thermoelectric device substrate 10. For example, insertion holes are provided in the second insulating board 21, so that the electrode portions 25a of the heat exchanging members 25 protrude slightly from the one surface of the second insulating board 21 through the insertion holes. Accordingly, when the one end surface of each electrode portion 25a is bonded to the electrode member 16 provided on the thermoelectric device substrate 10, the bonding can be easily performed because the electrode portions 25a slightly protrude toward the electrode member 16 from the one surface of the second insulating board 21.

The heat exchanging member 25 is arranged such that the electrode portion 25a and the heat exchanging portion 25b are extended along the flow direction of air as shown in FIGS. 7A and 7B. In this embodiment, the heat exchanging members 25 are arranged on the one surface side (refer to FIG. 1A) of the thermoelectric device substrate 10 in four lines in the flow direction of air. In contrast, the heat exchanging members 25 are arranged on the other surface side (refer to FIG. 1B) of the thermoelectric device substrate 10 in three lines in the flow direction of air.

That is, in this embodiment, all the heat exchanging members 25 arranged in the four lines in the flow direction of air on the one surface side (refer to FIG. 1A) of the thermoelectric device substrate 10 are set in the same direction, regardless of the arrangement of the electrode members 16. Similarly, all the heat exchanging members 25 arranged in the three lines in the flow direction of air on the other surface side (refer to FIG. 1B) of the thermoelectric device substrate 1 are set in the same direction along the arrangement of the electrode members 16.

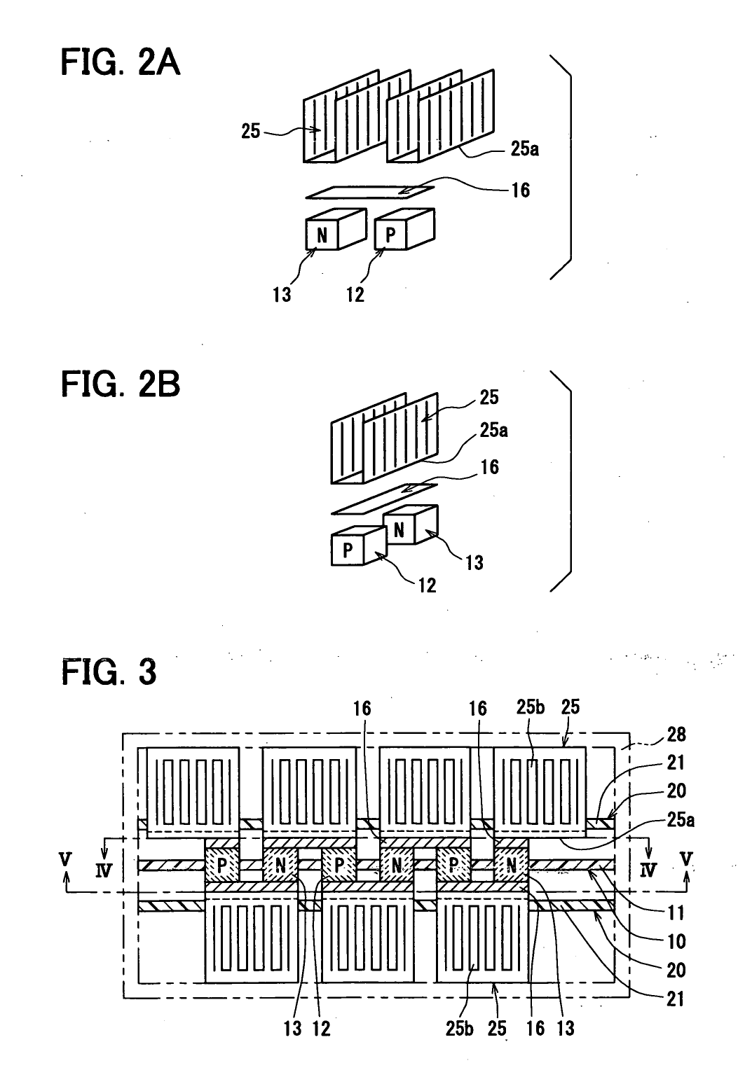

FIG. 2A is a perspective view showing the part IIA in FIG. 1A, and FIG. 2B is a perspective view showing the part IIB in FIG. 1A. As shown in FIG. 2A, a part area (e.g., about half area) of the end surface of the electrode portion 25a of the heat exchanging member 25 is bonded to the electrode member 16 positioned at the outer end of the thermoelectric device groups. In this embodiment, as shown in FIG. 2A, two heat exchanging members 25 are bonded to a single electrode member 16 that extends in a direction perpendicular to the extending direction of the electrode portion 25a, at the outer end of the thermoelectric device groups. Therefore, all area of the end surface of the electrode portion 25a of the heat exchanging member 25 is not bonded to the electrode member 16 positioned at the outer end of the thermoelectric device groups. In contrast, approximately all area of the end surface of the electrode portion 25a of each heat exchanging member 25 is bonded to the electrode member 16 at the inside (i.e., the second and third lines in FIG. 1A) of the thermoelectric device groups.

Because two heat exchanging members 25 are arranged relative to the electrode member 16 which connects the adjacent thermoelectric devices 12, 13 positioned at the outer end (e.g., the first and fourth lines in FIG. 1A), all the heat exchanging members 25 of the thermoelectric transducer can be formed into the same shape and can be arranged in the same direction as shown in FIGS. 1A and 1B. Adjacent heat exchanging members 25 can be arranged in the second insulating board 21 with a predetermined clearance therebetween so that the adjacent heat exchanging members 25 are electrically insulated from each other.

DC power inputted from the terminal 24a, as shown in FIG. 4, flows from the right upper electrode member 16 to the N-type thermoelectric device 13 and then flows in series through the adjacent P-type thermoelectric device 12 via the lower electrode member 16 and then flows from this P-type thermoelectric device 12 in series to the N-type thermoelectric device 13 via the upper electrode member 16. In other words, the electrode members 16 are connected to the thermoelectric devices 12, 13 in such a way that the DC power can flow in series to both ends of the thermoelectric devices 12, 13.

At this time, the upper electrode members 16 shown in FIG. 4 constructing the PN junctions are brought to a high temperature state by the Peltier effect and the lower electrode members 16 shown in FIG. 5 constructing the NP junctions are brought to a low temperature state. That is, as shown in FIG. 3, air-flowing passages are formed on both sides of the thermoelectric device substrate 10 by the case member 28 and the thermoelectric device substrate 10 used as a partition wall. When air flows through the air-flowing passages, heat is exchanged between the heat exchanging portions 25b and air, thereby air can be heated by the upper heat exchanging portions 25b and can be cooled by the lower heat exchanging portions 25b by means of the partition wall of the thermoelectric device substrate 10.

In this embodiment, the positive terminal of the DC power source is connected to the terminal 24a and the negative terminal of the DC power source is connected to the terminal 24b to apply the DC power to the terminal 24a. However, the positive terminal of the DC power source may be connected to the terminal 24b and the negative terminal of the DC power source may be connected to the terminal 24a to apply the DC power to the terminal 24b. However, at this time, the upper heat exchanging members 25 construct the heat absorbing portions and the lower heat exchanging members 25 constructs the heat radiating portions.

In this embodiment, the number of the heat exchanging members 25 arranged at the upper side is set larger than the number of the heat exchanging members 25 arranged at the lower side, as shown in FIGS. 1A and 1B. Therefore, the heat exchanging area on the heat radiating side or heat absorbing side of the heat exchanging members 25 can be effectively increased. Accordingly, it is possible to effectively improve thermoelectric converting efficiency by increasing an air blowing amount.

Next, a method for assembling a thermoelectric transducer will be described. First, a plurality of P-type thermoelectric devices 12 and a plurality of N-type thermoelectric devices 13 are formed and arranged alternately in a lattice pattern in holes formed in the first insulating board 11, to form the thermoelectric device substrate 10 having the thermoelectric devices 12, 13 integrally mounted on the first insulating board 11.

Then, a plurality of electrode members 16 each formed in the shape of a plate are located on the end surfaces of the thermoelectric devices 12, 13 adjacent to each other, as shown in FIG. 6. Then, the electrode members 16 are soldered to the thermoelectric devices 12, 13 so as to form the thermoelectric device substrate 10.

For example, the electrode members 16 arranged on the upper side of the first insulating board 11 in FIG. 6 form PN junctions to electrically connect adjacent thermoelectric devices 12, 13 in series, and the electrode members 16 arranged on the lower side of the first insulating board 11 in FIG. 6 form NP junctions to electrically connect adjacent thermoelectric devices 12, 13 in series. The thermoelectric device substrate 10 may be manufactured by the use of a mounter of a manufacturing apparatus for mounting semiconductors and electronic components on a control substrate.

On the other hand, the heat exchanging members 25 having the same shape are arranged in a lattice pattern and is integrated with the second insulating board 21 to form an integrate structure, as shown in FIG. 6. For example, the heat exchanging members 25 on the heat radiating side are arranged in four lines in the flow direction of air so as to form the heat radiating/absorbing substrate 20 on the heat radiating side, and the heat exchanging members 25 on the heat absorbing side are arranged in three lines in the flow direction of air so as to form the heat radiating/absorbing substrate 20 on the heat absorbing side.

Because the heat exchanging members 25 with the same shape are used, the heat exchanging members 25 can be easily formed by using one kind molding die, thereby assembling operation for assembling the heat absorbing/radiating substrate 20 can be made easy.

Furthermore, because all the heat exchanging members 25 are arranged in the same direction, assembling performance of the thermoelectric transducer can be greatly improved, and heat transmitting area on the heat radiating side can be greatly improved.

Then, the electrode device substrate 10 is sandwiched between and combined with the heat absorbing/radiating substrate 20 on the heat radiating side and the heat absorbing/radiating substrate 20 on the heat absorbing side. The respective electrode devices 16 are made to abut against and soldered together to the respective electrode portions 25a of the heat exchanging member 25. Then, the case members 28 are combined with the heat absorbing/radiating substrates 20 to form air passages on the upper side and the lower side, thereby the heat radiating part and the heat absorbing part are formed on the upper side and the lower side of the thermoelectric device substrate 10. By flowing air through these heat radiating and absorbing parts, cold air and hot air can be obtained. The thermoelectric transducer like this can be applied to an apparatus for cooling a heat generating component such as semiconductor and electric component and for heating of a heating unit.

In this embodiment, the heat exchanging members 25 are arranged in the insertion holes provided in the second insulating substrate 21 so as to be integrated with the second insulating substrate 21. However, the heat exchanging members 25 can be integrated with the second insulating substrate 21 by using other method such as an insert-molding or a molding process.

In the thermoelectric transducer according to the first embodiment, the heat exchanging members 25, each of which is bonded to the electrode member 16 connecting the adjacent thermoelectric devices 12, 13, are formed by the same shape in the electrode portions 25a and the heat exchanging portions 25b. In addition, the electrode portions 25a and the heat exchanging portions 25b of the heat exchanging members 25 are arranged in the same direction in each heat exchanging member 25, as shown in FIGS. 7A and 7B. Accordingly, the heat exchanging members 25 can be easily bonded to the electrode member 16.

Furthermore, at the outer end of the thermoelectric device group, as shown in FIG. 2A, the two heat exchanging members 25 are arranged so that each heat exchanging member 25 extends in an extension direction that is approximately perpendicular to an elongated direction (connection direction of the adjacent thermoelectric devices 12, 13) of the electrode member 16. Therefore, the heat exchanging area of the heat exchanging portions 25b of the heat exchanging members 25 on the heat radiating side can be greatly increased. As a result, thermoelectric converting efficiency can be effectively improved.

### Second Embodiment

In the above-described first embodiment, each electrode member 16 arranged on the adjacent thermoelectric devices 12, 13 at the outer end of the thermoelectric device groups is formed into the same shape as that of the electrode member 16 arranged on the adjacent thermoelectric devices 12, 13 positioned inside of the outer end of the thermoelectric device groups, as shown in FIGS. 2A and 2B. Therefore, the electrode member 16 arranged on the adjacent thermoelectric devices 12, 13 at the outer end of the thermoelectric device groups extend in a direction perpendicular to the flow direction of air, and a part of each of the two heat exchanging members 25 is bonded to the electrode member 16. In contrast, in the second embodiment, the surface area of the electrode member 16 arranged on the adjacent thermoelectric devices 12, 13 at the outer end of the thermoelectric device groups is enlarged.

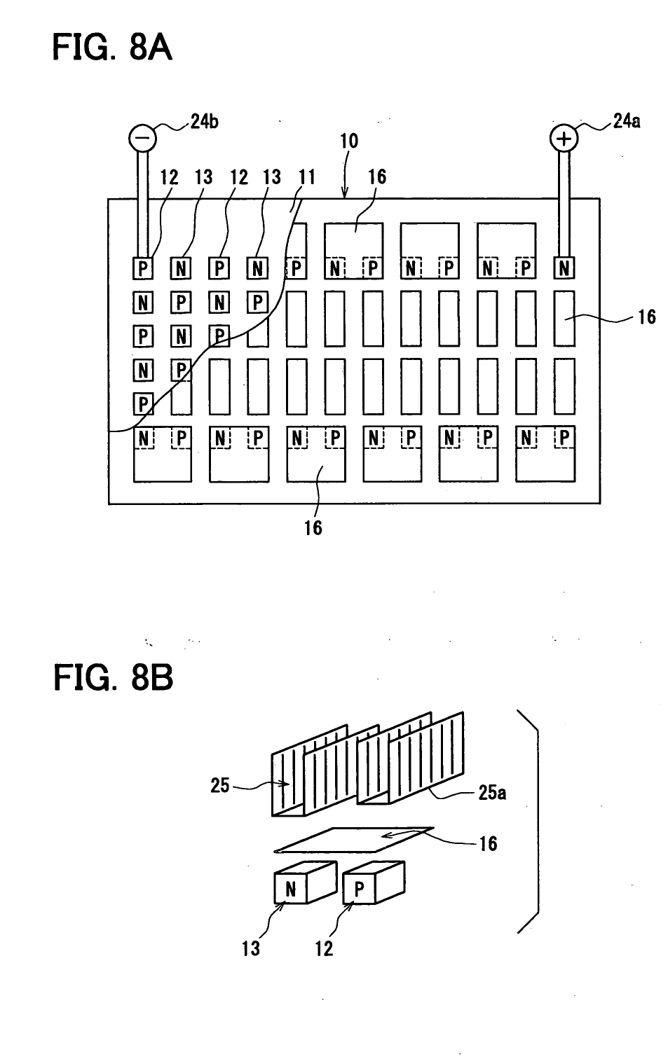

For example, as shown in FIG. 8A and 8B, the electrode member 16 arranged on the adjacent thermoelectric devices 12, 13 at the outer end of the thermoelectric device group is formed into substantially a regular tetragon shape having a dimension equal to the major dimension of the rectangular electrode member 16 arranged on the adjacent thermoelectric devices 12, 13 inside the outer end of the thermoelectric device groups. In this case, all the areas of the electrode portions 25a of the two heat exchanging members 25 are bonded to the electrode member 16 at the outer end of the thermoelectric device group. Even in this case, all the heat exchanging members 25 can be arranged in the same direction relative to the flow direction of air, similarly to the above-described first embodiment.

According to the second embodiment, because all the surface area of the electrode portions 25a of the two heat exchanging members 25 are bonded to each electrode member 16 at the outer end of the thermoelectric device groups, as shown in FIG. 8B. Therefore, contact area between each electrode member 16 at the outer end and the electrode portions 25a of the heat exchanging members 25 can be effectively increased thereby improving heat transmitting efficiency. Furthermore, when the heat transmitting area at the outer end of the thermoelectric device groups is increased on the air inlet side by the electrode member 16, the heat transmitting efficiency can be more effectively improved because a temperature difference between air and the heat exchanging portions 25 is enlarged at the air inlet portion.

### Third Embodiment

In the above-described first and second embodiments, the heat exchanging member 25 is bonded to the adjacent thermoelectric devices 12, 13 through the electrode member 16, while all the heat exchanging members 25 are formed into the same shape. In contrast, in the third embodiment, the electrode portions 25a of the heat exchanger members 25 are directly bonded to the thermoelectric devices 12, 13, while all the heat exchanging members 25 are formed into the same shape.

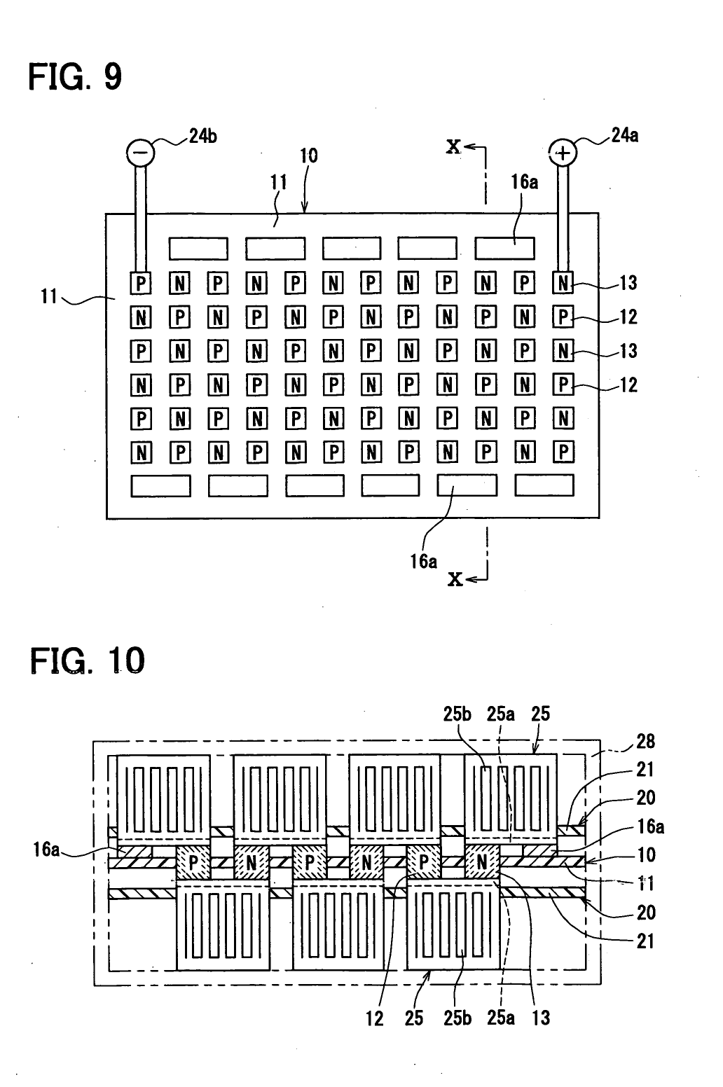

For example, as shown in FIGS. 9 and 10, an electrode member 16a is located to the first insulating board 11, so as to electrically connect with each other the electrode portions 25a of the two heat exchanging members 25 at the outer end of the thermoelectric groups. In this case, the electrode portions 25a of the two heat exchanging members 25 at the outer end of the thermoelectric groups can be electrically connected with each other through the electrode member 16a. The electrode member 16a can be formed from a plate member made of an electrical conduct material such as copper.

For example, the two heat exchanging members 25 are arranged on the adjacent thermoelectric devices 12, 13 at an outer end of the thermoelectric device groups such that the electrode portions 25a of the two heat exchanging members 25 are located, respectively, to the N-type thermoelectric device 13 and the P-type thermoelectric device 12. Furthermore, the N-type thermoelectric device 13 and the P-type thermoelectric device 12 at the outer end are electrically connected to each other via the electrode portion 16a.

The electrode portion 25a of each heat exchanging member 25 can be directly bonded to adjacent thermoelectric devices 12, 13 to electrically connect the adjacent thermoelectric devices through the electrode portion 25a, at the inner side of the outer end of the thermoelectric device groups. Even in the third embodiment, it is possible to use the same-shaped heat exchanging members 25 and to arrange the heat exchanging members 25 in the same direction.

The electrode member 16a for electrically connecting the electrode portions 25a of the two heat exchanging members 25 can be formed separate from the first insulating board 11 and can be formed into the other shape, only when the adjacent thermoelectric devices 12, 13 at the outer end are electrically connected with each other through the electrode member 16a.

In this embodiment, when the thickness of the electrode portion 25a of the heat exchanging member 25 is madder thicker, the electrode portion 25a of the heat exchanging member 25 can be easily directly bonded to the adjacent thermoelectric devices 12, 13. In the third embodiment, the arrangement direction and the shape of the heat exchanging members 25, which are directly connected to the thermoelectric devices 12, 13, can be made similarly to the above-described first embodiment.

### Other Embodiments

Although the present invention has been fully described in connection with the preferred embodiments thereof with reference to the accompanying drawings, it is to be noted that various changes and modifications will become apparent to those skilled in the art.

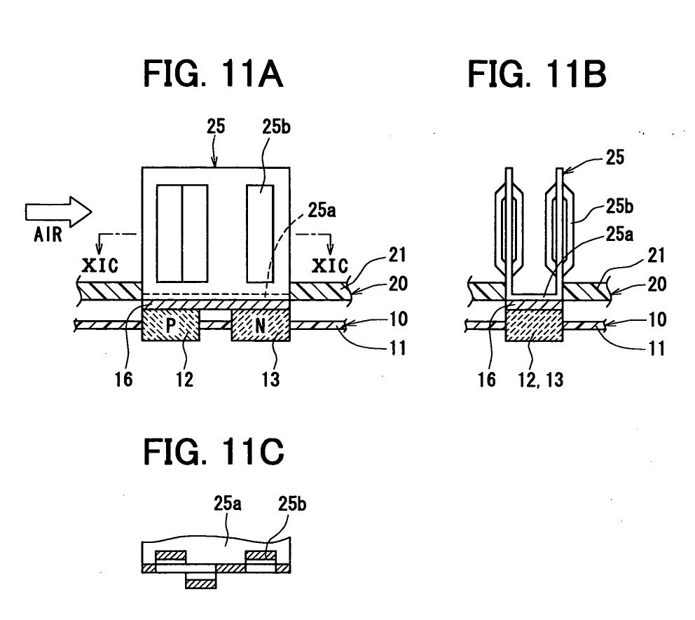

For example, in the above-described embodiment, the heat exchanging portion 25b of the heat exchanging member 25 can be formed into other shape such as an offset shape shown in FIGS. 11A-11C.

In the above-described embodiments, the heat exchanging members 25 can be arranged in lines other than three or four in the flow direction of air.

Such changes and modifications are to be understood as being within the scope of the present invention as defined by the appended claims.

What is claimed is:

1. A thermoelectric transducer comprising:
a thermoelectric device substrate that includes a plurality of P-type thermoelectric devices, a plurality of N-type thermoelectric devices, and an insulating board for holding the plurality of P-type thermoelectric devices and N-type thermoelectric devices, wherein the plurality of P-type thermoelectric devices and N-type thermoelectric devices are alternately arranged on the insulating board;
a plurality of electrode members each of which is connected to two end portions of adjacent N-type thermoelectric device and P-type thermoelectric device for electrically connecting the adjacent N-type thermoelectric device and P-type thermoelectric device; and
a plurality of heat exchanging members each of which includes an electrode portion connectable to the electrode member, and a heat exchanging portion for exchanging heat transmitted from the electrode portion, wherein:
the plurality of heat exchanging members are located at two sides of the thermoelectric device substrate to form a heat absorbing part and a heat radiating part partitioned from each other by the thermoelectric device substrate;
the electrode portions and the heat exchanging portions have, respectively, the same shapes, in all the heat exchanging members; and
the electrode portions and the heat exchanging portions are arranged in the same direction in all the heat exchanging members of each of the heat absorbing part and the heat radiating part.

2. The thermoelectric transducer according to claim 1, wherein:
the plurality of N-type thermoelectric devices and the plurality of P-type thermoelectric devices are arranged to form plural thermoelectric device groups arranged in plural lines in an arrangement direction;
each of the plural thermoelectric device groups is constructed with a pair of the N-type thermoelectric device and the P-type thermoelectric device electrically connected to each other by the electrode member;
two heat exchanging members are arranged on one electrode member that connects the N-type thermoelectric device and the P-type thermoelectric device in a direction perpendicular to the arrangement direction, at an outer end of the thermoelectric device groups;
the N-type thermoelectric device and the P-type thermoelectric device in each thermoelectric device group inside of the outer end are electrically connected by one electrode member extending in a direction parallel to the arrangement direction; and
the two heat exchanging members extend in the arrangement direction at the outer end of the thermoelectric device groups.

3. The thermoelectric transducer according to claim 2, wherein:
each of the heat exchanging members has approximately a U-shape having a bottom part used as the electrode portion and protruding portions used as the heat exchanging portion protruding from the bottom portion at two ends of the bottom portion;
each of the electrode members is elongated in an extension direction to electrically connect the N-type thermoelectric device and the P-type thermoelectric device of each thermoelectric device group; and
a part of each electrode portion of the two heat exchanging members is bonded to the electrode member at the outer end of the thermoelectric device groups.

4. The thermoelectric transducer according to claim 3, wherein each of the electrode portions and each of the heat exchanging portions of the two heat exchanging members at the outer end of the thermoelectric device groups extend in a direction approximately perpendicular to the extending direction of the electrode member at the outer end of the thermoelectric device groups.

5. The thermoelectric transducer according to claim 1, wherein each electrode member has a surface area approximately equal to a surface area of the electrode portion.

6. The thermoelectric transducer according to claim 1, wherein
at least in the heat radiating part, the two heat exchanging members are arranged on the one electrode member to extend in the arrangement direction at an outer end of the thermoelectric device groups.

7. The thermoelectric transducer according to claim 1, wherein:
the plurality of N-type thermoelectric devices and the plurality of P-type thermoelectric devices are arranged to form plural thermoelectric device groups arranged in plural lines in an arrangement direction;
each of the plural thermoelectric device groups is constructed with a pair of the N-type thermoelectric device and the P-type thermoelectric device electrically connected to each other by the electrode member;
two heat exchanging members are arranged on one electrode member at an outer end of the thermoelectric device groups; and
the electrode member arranged at the outer end of the thermoelectric device groups has a surface area to connect the N-type thermoelectric device and the P-type thermoelectric device in a direction perpendicular to the arrangement direction and to connect the electrode portions of the two heat exchanging members with each other.

8. A thermoelectric transducer comprising:
a thermoelectric device substrate that includes a plurality of P-type thermoelectric devices, a plurality of N-type thermoelectric devices, and an insulating board for holding the plurality of P-type thermoelectric devices and N-type thermoelectric devices, wherein the plurality of P-type thermoelectric devices and N-type thermoelectric devices are alternately arranged on the insulating board; and
a plurality of heat exchanging members each of which includes an electrode portion bonded to two end portions of adjacent N-type thermoelectric device and P-type thermoelectric device for electrically connecting the adjacent N-type thermoelectric device and P-type thermoelectric device, and a heat exchanging portion for exchanging heat transmitted from the electrode portion, wherein:
the plurality of heat exchanging members are located at two sides of the thermoelectric device substrate to form a heat absorbing part and a heat radiating part partitioned from each other by the thermoelectric device substrate;
the electrode portions and the heat exchanging portions have, respectively, the same shapes, in all the heat exchanging members; and
the electrode portions and the heat exchanging portions are arranged in the same direction in all the heat exchanging members in each of the heat absorbing part and the heat radiating part.

9. The thermoelectric transducer according to claim 8, wherein:
the plurality of N-type thermoelectric devices and the plurality of P-type thermoelectric devices are arranged to form plural thermoelectric device groups arranged in plural lines in an arrangement direction;
each of the plural thermoelectric device groups is constructed with a pair of the N-type thermoelectric device and the P-type thermoelectric device electrically connected to each other by the electrode portion;
two heat exchanging members are arranged on one thermoelectric device group at an outer end of the thermoelectric device groups such that the electrode portions of the two heat exchanging members are located, respectively, to the N-type thermoelectric device and the P-type thermoelectric device; and
the N-type thermoelectric device and the P-type thermoelectric device of the one thermoelectric device group are electrically connected to each other.

10. The thermoelectric transducer according to claim 9, wherein:
each of the heat exchanging members has approximately a U-shape having a bottom part used as the electrode portion and protruding portions used as the heat exchanging portion protruding from the bottom portion at the two sides of the bottom portion; and
a part of each electrode portion of the two heat exchanging members is bonded to the electrode portion at the outer end of the thermoelectric device groups.

11. The thermoelectric transducer according to claim 9, wherein each of the electrode portions of the two heat exchanging members at the outer end of the thermoelectric device groups extends in a direction approximately perpendicular to a connecting direction of the N-type thermoelectric device and P-type thermoelectric device at the outer end of the thermoelectric device groups.

12. The thermoelectric transducer according to claim 8, further comprising
a plurality of electrode members each of which is disposed to electrically connect the electrode portions of the two heat exchanging members, connected to the N-type thermoelectric device and the P-type thermoelectric device at the outer end of the thermoelectric device groups.

13. The thermoelectric transducer according to claim 9, wherein
at least in the heat radiating part, the two heat exchanging members are arranged on the one electrode member to extend in the arrangement direction at an outer end of the thermoelectric device groups.
